(19) United States
(12) Patent Application Publication
(10) Pub. No.: US 2024/0113741 A1
(43) Pub. Date: Apr. 4, 2024

(54) DEVICE AND METHOD FOR LOW OUTPUT VOLTAGE SPREAD IN CURRENT MODE TRANSMITTER

(71) Applicant: STMicroelectronics International N.V., Geneva (CH)

(72) Inventors: Sameer VASHISHTHA, Greater Noida (IN); Kirtiman Singh RATHORE, Noida (IN); Paras GARG, Noida (IN)

(73) Assignee: STMicroelectronics International N.V., Geneva (CH)

(21) Appl. No.: 18/471,162

(22) Filed: Sep. 20, 2023

Related U.S. Application Data
(60) Provisional application No. 63/378,025, filed on Sep. 30, 2022.

(51) Int. Cl. H04B 1/44; H03K 19/00; H04B 17/11

(52) U.S. Cl. CPC H04B 1/44; H03K 19/0005; H04B 17/11

(57) ABSTRACT

An integrated circuit includes a current mode transmitter. The current mode transmitter includes a first resistor and a second resistor. The resistance of the first resistor is adjusted by measuring the resistance, generating a resistance trimming code based on the measured resistance, and writing the first resistance trimming code to a first register. The resistance of the second resistor is adjusted by generating a second resistance trimming code based on the first resistance trimming code and writing the second resistance trimming code to a second register.

### BACKGROUND

### Technical Field

The present disclosure is related to integrated circuits, and more particularly, to integrated circuits that include current mode transmitters.

### Description of the Related Art

Integrated circuits are utilized for a large variety of applications. In many applications, it is desirable to transmit data from one device to another. Integrated circuits can be utilized in various ways to transmit and receive data. Integrated circuits may transmit data to other integrated circuits on a same printed circuit board or in other configurations or systems.

One method of data transmission is current mode transmission. In current mode transmission, data is transmitted by modulating the current flowing in a transmission medium. This can be a highly effective way to transmit signals. Current mode transmitters may utilize resistors as part of the current mode transmission and reception.

However, variations in wafer processing while forming the integrated circuits can result in resistors having resistances of the different than the design specifications. This can result in poorly functioning current mode transceivers. Poorly functioning current mode transceivers can result in loss of data in transmission, increased power consumption, and other problems.

All of the subject matter discussed in the Background section is not necessarily prior art and should not be assumed to be prior art merely as a result of its discussion in the Background section. Along these lines, any recognition of problems in the prior art discussed in the Background section or associated with such subject matter should not be treated as prior art unless expressly stated to be prior art. Instead, the discussion of any subject matter in the Background section should be treated as part of the inventor's approach to the particular problem, which, in and of itself, may also be inventive.

### BRIEF SUMMARY

Embodiments of the present disclosure provide a method and device for efficiently and effectively trimming the resistance of multiple resistors of a current mode transmitter of an integrated circuit. Embodiments of the present disclosure measure the resistance of a first resistor of the current mode transmitter and generate a first trimming code based on a difference between the measured resistance and an expected resistance. The first trimming code is written to a register that controls the value of the first resistor. Rather than measuring the resistance of a second resistor, a second resistor trimming code is generated based on the first resistor trimming code. The second resistor trimming code is written to a register that controls the value of the second resistor. In this way, a single resistor measurement can be utilized to generate resistor trimming codes for multiple resistors.

In one embodiment, a method includes measuring a resistance of a first resistor of a current mode transceiver. The first resistor is external to a transmission driver of the current mode transceiver. The method includes generating a first trimming code based on a difference between the resistance of the first resistor and a reference resistance. The method includes adjusting the resistance of the first resistor by storing the first trimming code in a memory associated with the first resistor and adjusting a resistance of a second resistor internal to the transmission driver by storing a second trimming code in a second memory associated with the second resistor.

In one embodiment, an integrated circuit includes a current mode transceiver. The current mode transceiver includes a receiving driver, a first resistor coupled to the receiving driver, a transmission driver including a second resistor, a first register that stores a first resistor trimming code for the first resistor, and a second register that stores a second resistor trimming code for the second resistor.

In one embodiment, a method includes measuring a resistance of a first resistor of a current mode transceiver of an integrated circuit. The method includes adjusting the resistance of the first resistor based on the measured resistance of the first resistor. The method includes adjusting the resistance of a second resistor of the current mode transceiver based on the measured resistance of the first resistor.

### BRIEF DESCRIPTION OF THE SEVERAL VIEWS OF THE DRAWINGS

Reference will now be made by way of example only to the accompanying drawings. In the drawings, identical reference numbers identify similar elements or acts. In some drawings, however, different reference numbers may be used to indicate the same or similar elements. The sizes and relative positions of elements in the drawings are not necessarily drawn to scale. For example, the shapes of various elements and angles are not necessarily drawn to scale, and some of these elements may be enlarged and positioned to improve drawing legibility.

FIG. 1 is a schematic diagram of a system including a current mode transmitter, according to one embodiment.

FIG. 2 is a schematic diagram of a resistor of a current mode transmitter, according to one embodiment.

FIG. 3 is a schematic diagram of a transmission driver of a current mode transmitter, according to one embodiment.

FIG. 4 is a schematic diagram of a resistor of a transmission driver of a current mode transmitter, according to one embodiment.

FIG. 5A is an illustration of a wafer including a plurality of integrated circuits, according to one embodiment.

FIG. 5B is an illustration of an integrated circuit of the wafer of FIG. 5A, according to one embodiment.

FIG. 6 is a flow diagram of a method for trimming resistances of a current mode transmitter, according to one embodiment.

### DETAILED DESCRIPTION

In the following description, certain specific details are set forth in order to provide a thorough understanding of various disclosed embodiments. However, one skilled in the relevant art will recognize that embodiments may be practiced without one or more of these specific details, or with other methods, components, materials, etc. In other instances, well-known systems, components, and circuitry associated with integrated circuits have not been shown or described in detail, to avoid unnecessarily obscuring descriptions of the embodiments.

Unless the context requires otherwise, throughout the specification and claims which follow, the word “comprise” and variations thereof, such as, “comprises” and “comprising” are to be construed in an open, inclusive sense, that is, as “including, but not limited to.” Further, the terms “first,” “second,” and similar indicators of sequence are to be construed as interchangeable unless the context clearly dictates otherwise.

Reference throughout this specification to “one embodiment” or “an embodiment” means that a particular feature, structure or characteristic described in connection with the embodiment is included in at least one embodiment. Thus, the appearances of the phrases “in one embodiment” or “in an embodiment” in various places throughout this specification are not necessarily all referring to the same embodiment. Furthermore, the particular features, structures, or characteristics may be combined in any suitable manner in one or more embodiments.

As used in this specification and the appended claims, the singular forms “a,” “an,” and “the” include plural referents unless the content clearly dictates otherwise. It should also be noted that the term “or” is generally employed in its broadest sense, that is, as meaning “and/or” unless the content clearly dictates otherwise.

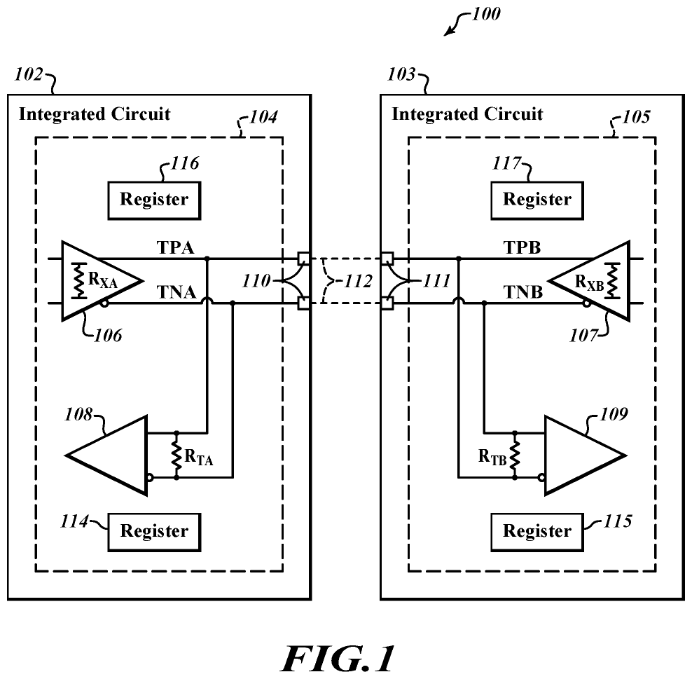

FIG. 1 is a schematic diagram of a system 100, according to one embodiment. The system 100 includes a first integrated circuit 102 and a second integrated circuit 103. The first and second integrated circuits 102 and 103 are coupled together in a current mode transmission scheme. As will be set forth in more detail below, the components of the integrated circuit 102 cooperate to effectively and efficiently adjust internal resistors to promote proper impedance matching.

The integrated circuits 102 and 103 are coupled together by a transmission medium 112. The transmission medium 112 can include structures, circuits, or components that enable the transmission of current mode data signals between the integrated circuit 102 and the integrated circuit 103.

In one embodiment, the system 100 is implemented on a printed circuit board. In this case, the integrated circuits 102 and 103 are coupled to the printed circuit board. The transmission medium 112 can include conductive signal traces that communicatively couple the first integrated circuit 102 to the second integrated circuit 103. The signal traces can include metal lines or other conductive structures. The transmission medium 112 can include other types of signal propagation structures without departing from the scope of the present disclosure.

The integrated circuit 102 includes a current mode transmitter 104. The current mode transmitter 104 may also be termed a current mode transceiver. This is because the current mode transmitter 104 can transmit data to the integrated circuit 103 and can receive data from the integrated circuit 103. In this way, the current mode transmitter 104 is a current mode transceiver.

The current mode transmitter 104 includes a transmission driver 106 and a receiving driver 108. The transmission driver 106 can be utilized to transmit data to the integrated circuit 103. The receiving driver 108 can be utilized to receive data from the integrated circuit 103. Further details regarding the transmission driver 106 and the receiving driver 108 are provided below.

The current mode transceiver 104 includes a first transmission line TPA and a second transmission line TNA. The first transmission line TPA is coupled to a first output of the transmission driver 106. The transmission line TNA is coupled to a second output of the transmission driver 106. The transmission line TPA is also coupled to a first input of the receiving driver 108. The transmission line TNA is also coupled to a second input of the receiving driver 108. The transmission lines TPA and TNA are each coupled to a respective terminal 110 of the integrated circuit 102.

The current mode transmitter 104 can operate in a transmission mode or in a receiving mode. In the transmission mode, the receiving driver 108 is disabled, and the transmission driver 106 is enabled. The transmission driver 106 drives currents through the transmission lines TPA and TNA. The data values may be read by the integrated circuit 103 as voltage differences across the corresponding transmission lines TPA and TNA of the integrated circuit 103.

The current mode transmitter 104 includes a resistor RTA. The resistor RTA is coupled between the first and second inputs of the transmission receiver 108. The resistor RTA is effectively coupled between the transmission lines TPA and TNA. As will be set forth in more detail below, the receiving driver 108 may read data in the receiving mode as voltage differences across the resistor RTA. Though not shown in FIG. 1, the resistor RTA may be selectively coupled and decoupled from the transmission lines TPA and TNA by operation of switches. Accordingly, in the data receiving mode the coupling switches may be closed, thereby coupling the resistor RTA between the transmission lines TPA and TNA. In the data transmission mode, the coupling switches may be open, thereby decoupling the resistor RTA from the transmission lines TPA and TNA.

The transmission driver 106 includes an internal resistor RXA. The transmission driver 106 utilizes the internal resistor RXA to drive currents through the transmission lines TPA and TNA. Further details regarding the internal resistor RXA will be provided below.

The integrated circuit 103 includes a current mode transmitter 105. The current mode transmitter 105 may also be termed a current mode transceiver. This is because the current mode transmitter 105 can transmit data to the integrated circuit 102 and can receive data from the integrated circuit 102. In this way, the current mode transmitter 105 is a current mode transceiver.

The current mode transmitter 105 includes a transmission driver 107 and a receiving driver 109. The transmission driver 107 can be utilized to transmit data to the integrated circuit 102. The receiving driver 109 can be utilized to receive data from the integrated circuit 102.

The current mode transceiver 105 includes a first transmission line TPB and a second transmission line TNB. The first transmission line TPB is coupled to a first output of the transmission driver 107. The transmission line TNB is coupled to a second output of the transmission driver 107. The transmission line TPB is also coupled to a first input of the receiving driver 109. The transmission line TPB is also coupled to a second input of the receiving driver 109. The transmission lines TPB and TNB are each coupled to a respective terminal 111 of the integrated circuit 103. The transmission line TPB is coupled to the transmission line TPA of the integrated circuit 102 via the transmission medium 112. The transmission line TNB is coupled to the transmission line TNA of the integrated circuit 102.

The current mode transmitter 105 can operate in a transmission mode or in a receiving mode. In the transmission mode, the receiving driver 109 is disabled, and the transmission driver 107 is enabled. The transmission driver 107 drives currents through the transmission lines TPB and TNB. The data values may be read by the integrated circuit 103 as voltage differences across the corresponding transmission lines TPB and TNB of the integrated circuit 103.

The current mode transmitter 105 includes a resistor RTB. The resistor RTB is coupled between the first and second inputs of the transmission receiver 109. The resistor RTB is effectively coupled between the transmission lines TPB and TNB. As will be set forth in more detail below, the receiving driver 109 may read data in the receiving mode as voltage differences across the resistor RTB. Though not shown in FIG. 1, the resistor RTB may be selectively coupled and decoupled from the transmission lines TPB and TNB by operation of switches. Accordingly, in the data receiving mode the coupling switches may be closed, thereby coupling the resistor RTB between the transmission lines TPB and TNB. In the data transmission mode, the coupling switches may be open, thereby decoupling the resistor RTB from the transmission lines TPB and TNB.

The transmission driver 107 includes an internal resistor RXA. The transmission driver 107 utilizes the internal resistor RXA to drive currents through the transmission lines TPA and TNA. Further details regarding the internal resistor RXA will be provided below.

The values of the resistors RTA and RXA play a role in impedance matching between the integrated circuits 102 and 103. It is beneficial that the impedances of the current mode transmitter 104 of the integrated circuit 102 be matched with the impedances of the current mode transmitter 105 of the integrated circuit 103.

In one embodiment, impedance matching may be accomplished by having a standard impedance value for both the integrated circuit 102 and the integrated circuit 103. In one example, impedance matching may be accomplished by ensuring that the resistors RXA and RXB have a same value and by ensuring that the resistors RTA and RTB have a same value. As the integrated circuit 102 and integrated circuit 103 are separately manufactured, individual integrated circuits, impedance matching may be achieved by ensuring that RTA and RXA have values that match specified values within an error tolerance and by ensuring that the resistors RTB and RXB have values that match specified values within an error tolerance. Impedance matching operations in accordance with principles of the present disclosure will be described primarily with relation to the integrated circuit 102, though the same or similar operations, components and processes can be utilized for the integrated circuit 103.

One obstacle for impedance matching is unwanted variance in the values of the resistors RTA and RXA. Such variance can occur as a result of process conditions. The integrated circuit 102 is processed while the integrated circuit 102 as part of a wafer on which a plurality of identical integrated circuits are patterned. The integrated circuits are formed by performing a large number of processing steps on the wafer. The processing steps can include photolithography steps, etching steps, deposition steps, epitaxial growth steps, and other types of processing steps. The integrated circuit 102 is diced or otherwise simulated from the wafer after processing is complete.

During processing, conditions such as temperature, pressure, gas flow rates, voltages, currents, and other conditions may play a role in the formation of features of the integrated circuits in the wafer. Some cases, there may be unintentional variations in these conditions. Such variations can result in variations in the features formed in the wafers. Accordingly, the exact initial values of the resistors RXA and RTA may vary from specified values based on variations in processing conditions. If such variations are not accounted for or addressed, then there may be improper impedance matching between the integrated circuit 102 and integrated circuit 103.

In one embodiment, variations in the resistance values of the resistors RXA and RTA due to processing conditions are addressed or corrected by trimming the resistance values of the resistors RTA and RXA after processing has been completed. In one embodiment, after processing of the wafer has been completed, and prior to dicing the integrated circuit 102 from the wafer, a testing process is performed on the integrated circuit 102. The testing process tests the resistance of the resistor RTA. If the resistance of the resistor RTA differs from a specified resistance by more than a threshold tolerance, then the trimming process is performed on the resistor RTA. The training process adjusts the resistance of the resistor RTA.

In one embodiment, the resistor RTA includes a plurality of sub-resistors connected in parallel between the transmission lines TPA and TNA. Each of the sub-resistors can be selectively coupled or decouple from the transmission lines TPA and TNA by selectively opening or closing the corresponding switches. The resistance of the resistor RTA is trimmed or adjusted by selectively coupling or decoupling the various sub-resistors from the transmission lines TPA and TNA.

In one embodiment, the integrated circuit 102 includes a register 114. The register 114 is associated with the resistor RTA. In particular, the register 114 stores a resistance trimming code. The value of the resistance trimming code controls which of the sub-resistors of the resistor RTA are coupled or decoupled from the transmission lines TPA and TNA. Accordingly, the register 114 correspond to type of memory of the integrated circuit 102. However, other types of memories can be utilized to store a resistor trimming code without departing from the scope of the present disclosure.

In one embodiment, the register 114 includes a plurality of data storage cells. Each data storage cell may store a single bit data value. Each data storage cell may be assigned file particular son resistor of the resistor RTA. The single bit data value indicates whether or not the sub-resistor is coupled or decouple from the transmission lines TPA and TNA. In one example, a value of 1 in a particular data storage cell of the register 114 causes the corresponding sub-resistor to be coupled between the transmission lines TPA and TNA. In one example, a value 0 in a particular data storage cell of the register 114 causes the corresponding sub-resistor to be decoupled from the transmission lines TPA and TNA. If the resistor RTA includes five sub-resistors, then the resistor trimming code may be a five bit code stored in five data cells of the register 114.

During calibration or trimming of the resistor RTA, the measurement of the initial resistance of the resistor RTA may indicate that the resistor RTA has a value that is greater than or less than the specified or expected resistance by a particular factor. Calibration or trimming of the resistor RTA is an accomplished by selecting a calibration code that will result in the resistor RTA having a value within an error tolerance of the expected value. The calibration process can include testing a plurality of calibration codes until a calibration code is found that results in the resistor RTA having a resistance that is substantially the same as the desired or specified resistance, within an error tolerance.

In one embodiment, the resistors RXA and RTA are formed at the same time or by the same processing steps during processing of the wafer from which the integrated circuit 102 is diced. For example, the resistors RXA and RTA may be formed by deposition and patterning of a resistive material such as polysilicon or another type of resistive material. Because the resistors RXA and RTA are formed of the same deposition and patterning processes, the resistors RXA and RTA will initially differ from their specified values by a same proportion. For example, if the resistance RTA is initially 10% higher than the specified or expected resistance value, the resistor RXA will also be 10% higher than the specified or expected resistance value.

In one embodiment, principles of the present disclosure trimmed the resistance of the resistor RXA based on the testing and trimming of the resistor RTA. In other words, the resistance of the resistor RXA does not need to be tested separately from the resistance of the resistor RTA during calibration. This is because the resistance of the resistor RXA will differ from the specified value by the same factor or proportion by which the resistor RTA differs from the specified value. As an example, the initial expected resistance of the resistor RTA may be 100 ohms and the initial expected resistance of the resistor RXA may be 1000 ohms. If the expected resistance of the resistor RTA is 100 ohms, but testing reveals that the actual initial resistance of the resistor RTA is 110 ohms, then it is known that the resistance of the resistor RXA will be 1100 ohms. Other expected values for the resistors RXA and RTA may be utilized without departing from the scope of the present disclosure.

In one embodiment, the integrated circuit 104 includes a register 116 associated with or coupled to the resistor RXA of the transmission driver 106. The resistor RXA may have a similar or same structure as the resistor RTA. In other words, the resistor RXA may include a plurality of sub-resistors that can be selectively coupled or decoupled. The register 116 can store a trimming code for the resistor RXA. The register 116 may be substantially identical to the register 114. The register 116 may include a plurality of data storage cells that each store a single bit data value and that are each associated with a particular son resistor of the resistor RXA.

In one embodiment, trimming of the resistor RXA is accomplished by storing the same trimming code from the register 114 in the register 116. In this case, the resistor RXA has a same number of sub-resistors as the resistor RTA. The value of the resistor RXA can be brought within an error tolerance of the specified or expected value of the resistor RTA by storing the same trimming code from the register 114 in the register 116.

In one embodiment, the resistor RXA does not have a same number sub-resistors as the resistor RTA. In this case, a trimming code is selected for the register 116 based on the trimming code 114. For example, if the trimming code stored in the resistor 114 reduces the resistance of the resistor RTA by 10% from an initial value, then the turning code is selected for the register 116 that will reduce the resistance of the resistor RXA by 10% from an initial value.

Because a trimming code is selected for the resistor RXA based on the trimming code selected for the resistor RTA, trimming of the resistor RXA can be efficiently and effectively performed. Furthermore, trimming of the resistor RXA can be performed without testing the resistance of the resistor RXA. Instead, testing of the resistor RTA can be utilized for trimming both the resistor RTA and the resistor RXA.

In one embodiment, a testing apparatus test the resistance of the resistor RXA and selects a trimming code for the resistor RXA. The testing apparatus may be external to the integrated circuit 102. The testing apparatus may calculate or select a trimming code for the resistor RTA based on the trimming code for the resistor RXA. Alternatively, an internal control circuit of the integrated circuit 102 can select the trimming codes for the resistor RXA and RTA based on a test value of the resistor RTA received from an external testing apparatus.

While the description herein describes testing the resistor RTA into trimming the resistor RXA based on the test of the resistor RTA, trimming of the resistor RTA may be achieved based on testing of the resistor RXA. In other words, either of the resistors RXA or RTA can first be tested and trimmed, and then the trimming of the other resistor can be accomplished based on the trimming code found for the first resistor.

The integrated circuit 102 can include various circuits and components not shown in FIG. 1. For example, the integrated circuit 102 may include a controller coupled to the current mode transmitter 104. The controller can control transmission and receiving of data via the current mode transmitter 104. The integrated circuit 102 can include memories, clock circuits, buffers, pre-drivers, data generators, and various other circuits or components.

The integrated circuit 103 may also include a register 115 associated with the resistor RTB and the register 117 associated with the resistor RXB. Testing a trimming of the resistors RTB and RXB can be accomplished in a same or similar manner as described in relation to the integrated circuit 102. Alternatively, the integrated circuit 103 may be different and have different components in the integrated circuit 102.

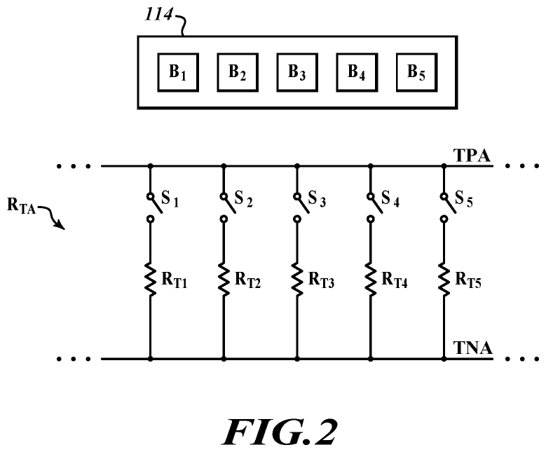

FIG. 2 is a schematic diagram of the resistor RTA of FIG. 1, according to one embodiment. In the example FIG. 2, the resistor RTA includes five sub-resistors RT1-RT5. FIG. 2 also illustrates a plurality of switches S1-S5. Each switch S1-S5 is coupled between one of the sub-resistors and the transmission line TPA. In particular, the switch S1 is coupled between the sub-resistor RT1 and the transmission line TPA. The switch S2 is coupled between the sub-resistor RT2 and the transmission line TPA. The switch S3 is coupled between the sub-resistor RT3 and the transmission line TPA. The switch S4 is coupled between the sub-resistor RT4 and the transmission line TPA. The switch S5 is coupled between the sub-resistor RT5 and the transmission line TPA.

The register 114 includes a plurality of bit cells B1-B5. Each of the bit cells B1-B5 is associated with one of the switches S1-S5, and the corresponding sub-resistor. In one example, the bit cell B1 is associated with the switch S1 and the sub-resistor RT1. In one example, the bit cell B2 is associated with the switch S2 and the sub-resistor RT2. In one example, the bit cell B3 is associated with the switch S3 and the sub-resistor RT3. In one example, the bit cell B4 is associated with the switch S4 and the sub-resistor RT4. In one example, the bit cell B5 is associated with the switch S5 and the sub-resistor RT5. The data value in the bit cell determines whether or not the corresponding switch is open or closed. A trimming code for the resistor RTA corresponds to the data value stored in each of the bit cells B1-B5, which in turn determines which of the sub-resistors RT1-RT5 are contributing to the overall resistance of the resistor RTA. Other numbers of sub-resistors, other configurations of switches, and other types of memories or trimming codes can be utilized without departing from the scope of the present disclosure.

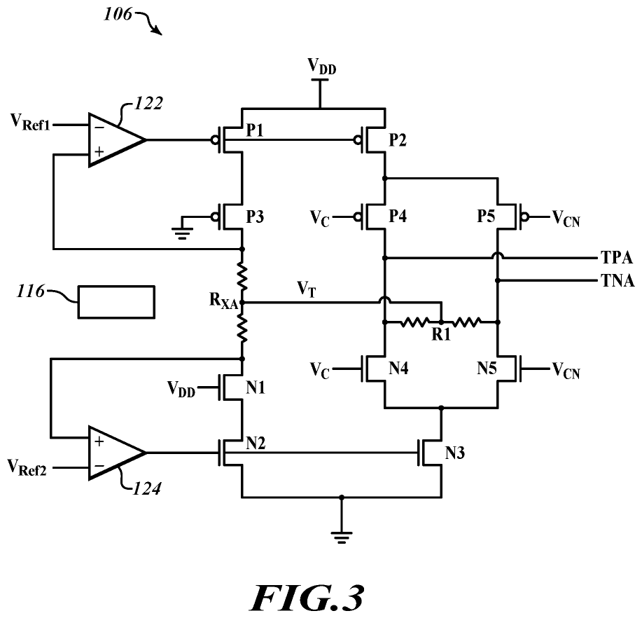

FIG. 3 is a schematic diagram of a transmission driver 106, according to one embodiment. The transmission driver 106 of FIG. 3 is one example of the transmission driver 106 of FIG. 1. The transmission driver 106 includes a plurality of P type transistors P1-P5, a plurality of N type transistors N1-N3, resistors RXA and R1, and comparators 122 and 124. FIG. 3 also illustrates the register 116 associated with the resistor RXA.

The source of the transistors P1 and P2 are coupled to VDD. The gate terminals of the transistors P1 and P3 are coupled to the output of the comparator 122. The source terminal of the transistor P3 is coupled to the drain terminal of the transistor P1. The gate terminal of the transistor P3 is coupled to ground. The drain terminal of the transistor P3 is coupled to the noninverting input of the comparator 122. The inverting input of the comparator 122 receives a first reference voltage Vref1.

The resistor RXA is coupled between the drain terminals of the transistors P3 and N1. The drain terminal of the transistor N1 is coupled to the noninverting input of the comparator 124. The inverting input of the comparator 124 receives the reference voltage Vref2. The gate terminal of the transistor N1 receives VDD. The gate terminals of the transistors N2 and N3 are coupled to the output of the comparator 124. The source terminals of the transistors N2 and N3 are coupled to ground.

The source terminals of the transistors P4 and P5 are coupled to the drain terminal of the transistor P2. The gate terminal of the transistor P4 receives the control voltage VC. VC is one of the inputs of the transmission driver 106. The gate terminal of the transistor P5 receives the complementary control voltage VCN. VCN is the logical complement of VC and is a second input of the transmission driver 106. The drain terminal of the transistor P4 is coupled to the drain terminal of the transistor N4. The drain terminal of the transistor P5 is coupled to the drain terminal of the transistor N5. The source terminals of the transistors N4 and N5 are coupled to the drain terminal of the transistor N3. The drain terminal of the transistor P4 is coupled to the transmission line TPA. The drain terminal of the transistor P5 is coupled to the transmission line TNA. The resistor R1 is coupled between the drain terminals of the transistors P4 and P5.

The resistors RXA and R1 are each shown as to resistors. The midpoint of the two resistors of RXA is coupled to the midpoint of the two resistors of the resistor R1. The midpoints of the resistors RXA and R1 are coupled together as a core tap voltage VT. The resistors RXA and R1 may have other configurations without departing from the scope of the present disclosure. The register 116 can store a resistance trimming code that trims the value of the resistor RXA.

The transistors P1 and P2 are coupled together in a current mirror configuration. A reference current flows through the transistors P1, P3, N1 and N2. A drive a current flows through the transistor P2, based on the reference current in accordance with the current mirror configuration. The drive current flowing to the transistor P2 and the control voltages VC and VCN drive data through the transmission lines TPA and TNA. The transmission driver 106 can have other configurations without departing from the scope of the present disclosure.

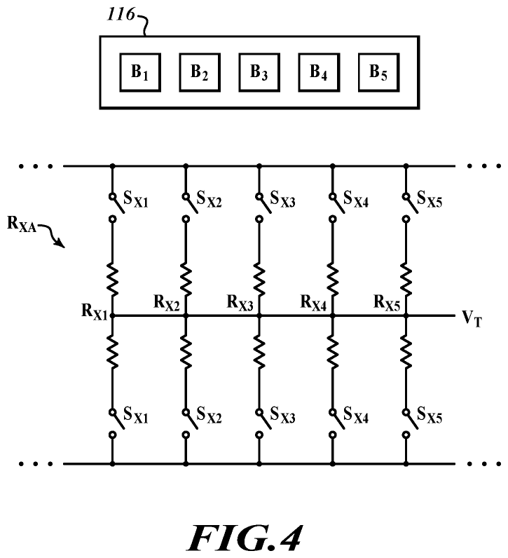

FIG. 4 is a schematic diagram of the resistor RXA of FIG. 3, according to one embodiment. The resistor RXA includes a plurality of pairs of sub-resistors RX1. Each pair of some resistors RX1-RX5 is coupled between the transmission lines TPA and TNA by the corresponding pair of switches SX1-SX5. For example, the switches SX1 are coupled between the pair some resistors RX1 and the transmission lines TPA and TNA. The switches SX2 are coupled between the pair some resistors RX2 and the transmission lines TPA and TNA. The switches SX3 are coupled between the pair some resistors RX3 and the transmission lines TPA and TNA. The switches SX4 are coupled between the pair some resistors RX4 and the transmission lines TPA and TNA. The switches SX5 are coupled between the pair some resistors RX5 and the transmission lines TPA and TNA. The midpoint of each of the pairs of resistors are coupled together and provide the core tap voltage VT.

The register 116 includes a plurality of bit cells B1-B5. Each of the bit cells B1-B5 is associated with one of the switches SX1-SX5, and the corresponding sub-resistor. In one example, the bit cell B1 is associated with the switches SX1 and the sub-resistors RX1. In one example, the bit cell B2 is associated with the switches SX2 and the sub-resistors RX2. In one example, the bit cell B3 is associated with the switch SX3 and the sub-resistors RX3. In one example, the bit cell B4 is associated with the switch SX4 and the sub-resistors RX4. In one example, the bit cell B5 is associated with the switch SX5 and the sub-resistors RX5. The data value in the bit cell determines whether or not the corresponding switches are open or closed. A trimming code for the resistor RXA corresponds to the data value stored in each of the bit cells B1-B5, which in turn determines which of the sub-resistors RX1-RX5 are contributing to the overall resistance of the resistor RXA. Other numbers of sub-resistors, other configurations of switches, and other types of memories or trimming codes can be utilized without departing from the scope of the present disclosure.

In one embodiment, each pair of switches SX1-SX5 are uniformly controlled. In other words, the switches SX1 are either both open or both closed, based on the value of the bit cell B1 in the register 116. The switches SX2 are either both open or both closed, based on the value of the bit cell B2 in the register 116. The switches SX3 are either both open or both closed, based on the value of the bit cell B3 in the register 116. The switches SX4 are either both open or both closed, based on the value of the bit cell B4 in the register 116. The switches SX5 are either both open or both closed, based on the value of the bit cell B5 in the register 116.

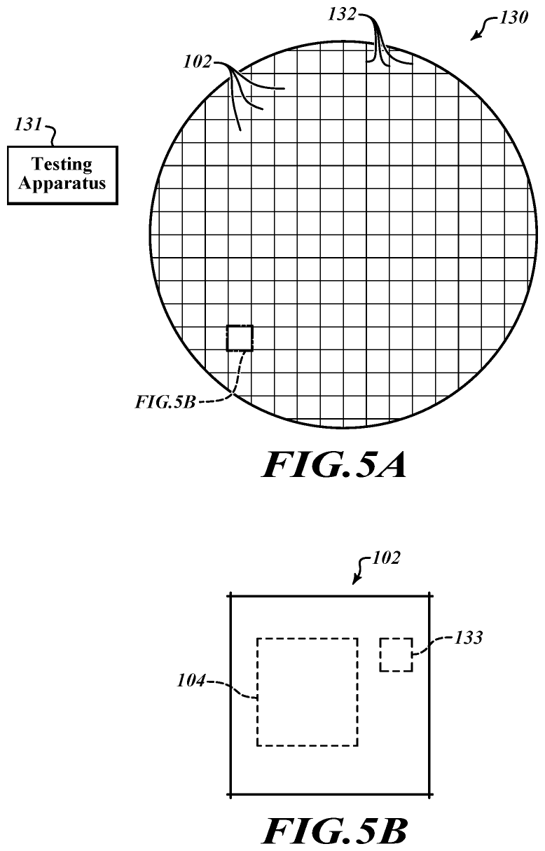

FIG. 5A illustrates a semiconductor wafer 130 and a testing apparatus 131, according to one embodiment. The wafer 130 includes a plurality of identical integrated circuits 102 separated from each other by the scribe lines 132. In FIG. 5A, processing of the wafer 130 is complete. Each integrated circuit 102 includes a current mode transmitter 104 as described in relation to FIG. 1.

The testing apparatus 131 is utilized to test the resistances of the resistors RTA (or RXA, as the case may be). The testing apparatus writes a trimming code to the register 114 based on the measured resistance of the resistor RTA and the expected or specified resistance of the resistor RTA. The testing apparatus 131 can then write a trimming code to the register 116 based on the trimming code written to the register 114. The trimming code written to the register 116 can be identical to the trimming code written to the register 114 or can be selected based on the trimming code written to the register 114. The testing apparatus 131 can include process probes that can be connected to contact pads or testing pads of each of the integrated circuits 102. The testing apparatus 131 can include control circuitry and other circuitry that can be utilized for performing calibration or testing of the integrated circuits 102. After testing and adjustment of the resistances, the integrated circuits 102 can be diced from the wafer 130.

FIG. 5B illustrates one of the integrated circuits 102 of the wafer 130 of FIG. 5A. The current mode transmitter 104 is illustrated in dashed lines. Testing pads 133 are also illustrated in dashed lines. The integrated circuit 102 can include contact pads and other components.

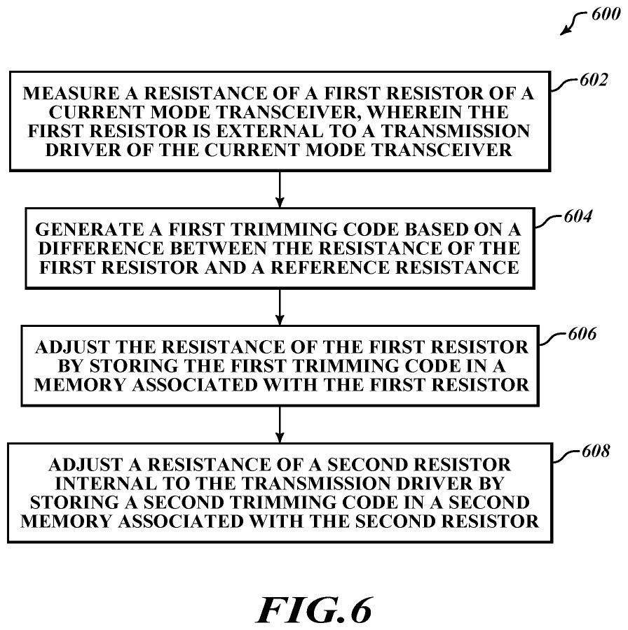

FIG. 6 is a flow diagram of a method 600, in accordance with one embodiment. The method 600 can utilize processes, components, and systems described in relation to FIGS. 1-5B. At 602, the method 600 includes measuring a resistance of a first resistor of a current mode transceiver, wherein the first resistor is external to a transmission driver of the current mode transceiver. At 604, the method 600 includes generating a first trimming code based on a difference between the resistance of the first resistor and a reference resistance. At 606, the method 600 includes adjusting the resistance of the first resistor by storing the first trimming code in a memory associated with the first resistor. At 608, the method 600 includes adjusting a resistance of a second resistor internal to the transmission driver by storing a second trimming code in a second memory associated with the second resistor.

In one embodiment, a method includes measuring a resistance of a first resistor of a current mode transceiver. The first resistor is external to a transmission driver of the current mode transceiver. The method includes generating a first trimming code based on a difference between the resistance of the first resistor and a reference resistance. The method includes adjusting the resistance of the first resistor by storing the first trimming code in a memory associated with the first resistor and adjusting a resistance of a second resistor internal to the transmission driver by storing a second trimming code in a second memory associated with the second resistor.

In one embodiment, an integrated circuit includes a current mode transceiver. The current mode transceiver includes a receiving driver, a first resistor coupled to the receiving driver, a transmission driver including a second resistor, a first register that stores a first resistor trimming code for the first resistor, and a second register that stores a second resistor trimming code for the second resistor.

In one embodiment, a method includes measuring a resistance of a first resistor of a current mode transceiver of an integrated circuit. The method includes adjusting the resistance of the first resistor based on the measured resistance of the first resistor. The method includes adjusting the resistance of a second resistor of the current mode transceiver based on the measured resistance of the first resistor.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A method, comprising:
measuring a resistance of a first resistor of a current mode transceiver, wherein the first resistor is external to a transmission driver of the current mode transceiver;
generating a first trimming code based on a difference between the resistance of the first resistor and a reference resistance;
adjusting the resistance of the first resistor by storing the first trimming code in a memory associated with the first resistor; and
adjusting a resistance of a second resistor internal to the transmission driver by storing a second trimming code in a second memory associated with the second resistor.

2. The method of claim 1, wherein the second trimming code is identical to the first trimming code.

3. The method of claim 1, wherein the second trimming code is different from the first trimming code.

4. The method of claim 3, comprising computing the second trimming code based on the first trimming code.

5. The method of claim 1, wherein the first resistor includes a plurality of first sub-resistors coupled in parallel.

6. The method of claim 5, wherein adjusting the resistance of the first resistor includes selectively opening and closing a plurality of first switches each coupled to a respective first sub-resistor.

7. The method of claim 6, wherein the second resistor includes a plurality of second sub-resistors coupled in parallel.

8. The method of claim 7, wherein adjusting the resistance of the second resistor includes selectively opening and closing a plurality of second switches each coupled to a respective second sub-resistor.

9. The method of claim 8, wherein the first resistor has a different number of first sub-resistor than a number of second sub-resistors of the second resistor.

10. The method of claim 1, comprising transmitting data in a current mode transmission scheme from the current mode transceiver.

11. An integrated circuit, comprising:
a current mode transceiver including:
a receiving driver;
a first resistor coupled to the receiving driver;
a transmission driver including a second resistor;
a first register that stores a first resistor trimming code for the first resistor; and
a second register that stores a second resistor trimming code for the second resistor.

12. The integrated circuit of claim 11, wherein the first resistor trimming code is the same as the second resistor trimming code.

13. The integrated circuit of claim 12, wherein the first resistor trimming code is different from the second resistor trimming code.

14. The integrated circuit of claim 11, comprising:
a plurality of first switches coupled to the first resistor, wherein the first resistor trimming code controls the first switches; and
a plurality of second switches coupled to the second resistor, wherein the second resistor trimming code controls the second switches.

15. The integrated circuit of claim 11, comprising:
a first transmission line coupled to a first input of the receiving driver, a first output of the transmission driver, and a first I/O terminal of the integrated circuit; and
a second transmission line coupled to a second input of the receiving driver, a second output of the transmission driver, and a second I/O terminal of the integrated circuit.

16. The integrated circuit of claim 15, wherein the first resistor is coupled between the first and second transmission lines.

17. The integrated circuit of claim 16, wherein the transmission driver is configured to drive data to the first and second I/O terminals via the first and second transmission lines, wherein receiving driver is configured to receive data from the first and second I/O terminals via the first and second transmission lines.

18. A method, comprising:
measuring a resistance of a first resistor of a current mode transceiver of an integrated circuit;
adjusting the resistance of the first resistor based on the measured resistance of the first resistor; and
adjusting the resistance of a second resistor of the current mode transceiver based on the measured resistance of the first resistor.

19. The method of claim 18, comprising dicing the integrated circuit from a wafer after adjusting the resistance of the first resistor.

20. The method of claim 18, wherein adjusting the resistance of the first resistor includes writing a first trimming code to a first register of the integrated circuit, wherein adjusting the resistance of the second resistor includes writing a second trimming code to a second register of the integrated circuit.
